(19) United States
(12) Patent Application Publication
(10) Pub. No.: US 2024/0242965 A1
(43) Pub. Date: Jul. 18, 2024

(54) AMORPHOUS BORON NITRIDE FILM, SEMICONDUCTOR DEVICE AND FIELD EFFECT TRANSISTOR INCLUDING SAME, AND METHOD OF MANUFACTURING BORON NITRIDE FILM

(71) Applicants: Samsung Electronics Co., Ltd., Suwon-si (KR); UNIST (ULSAN NATIONAL INSTITUTE OF SCIENCE AND TECHNOLOGY), Ulsan (KR)

(72) Inventors: Taejin CHOI, Suwon-si (KR); Minsu KIM, Ulsan (KR); Hyeonsuk SHIN, Ulsan (KR); Jaewon KIM, Suwon-si (KR); Taehoon KIM, Suwon-si (KR); Hyeonjin SHIN, Suwon-si (KR); Van Luan NGUYEN, Suwon-si (KR)

(73) Assignees: Samsung Electronics Co., Ltd., Suwon-si (KR); UNIST (ULSAN NATIONAL INSTITUTE OF SCIENCE AND TECHNOLOGY), Ulsan (KR)

(21) Appl. No.: 18/414,811

(22) Filed: Jan. 17, 2024

(30) Foreign Application Priority Data
Jan. 17, 2023 (KR) 10-2023-0006984

(51) Int. Cl. H01L 21/02; H01L 29/20; H01L 29/66; H01L 29/78

(52) U.S. Cl. CPC H01L 21/0254; H01L 21/02458; H01L 21/0262; H01L 29/2006; H01L 29/66795; H01L 29/7851

(57) ABSTRACT

Provided are an amorphous boron nitride film, and a semiconductor device, a field effect transistor and an image sensor which include the same, and a method of manufacturing the amorphous boron nitride film. The amorphous boron nitride film includes a carbon atom-doped amorphous boron nitride compound, wherein an sp² BN bonding structure and an sp³ BN bonding structure are included in the boron nitride film, an sp²/sp³ conjugated —C═C—C═C— dopant structure being distributed in 60% or less of the entire amorphous film.

### CROSS-REFERENCE TO RELATED APPLICATION

This application is based on and claims priority under 35 U.S.C. § 119 to Korean Patent Application No. 10-2023-0006984, filed on Jan. 17, 2023, in the Korean Intellectual Property Office, the disclosure of which is incorporated by reference herein in its entirety.

### BACKGROUND

Various example embodiments relate to an amorphous boron nitride film doped with or having carbon atoms, a semiconductor device and a field effect transistor which include the same, and a method of manufacturing the boron nitride film.

Integrated circuits of various electronic devices, including display devices, image sensors, field effect transistors, memory devices, and/or the like, can be manufactured by combining and connecting semiconductors, conductors, and insulators. For example, the integrated circuits of various electronic devices can be manufactured or fabricated by forming a plurality of unit elements on a substrate, and then stacking an interlayer insulating film and a wiring thereon.

As the degree of integration of an integrated circuit greatly increases, an interval between conductor patterns is gradually decreasing. Accordingly, the parasitic capacitance between conductor patterns is increased, which may result in deterioration of the performance, such as the electrical speed and/or power consumption, of an electronic device. For example, parasitic capacitance may delay the signal transmission of semiconductor devices. To reduce the parasitic capacitance, insulator materials having relatively low dielectric constants are proposed as interlayer insulating films.

### SUMMARY

Provided is an amorphous boron nitride film that maintains, or at least partially maintains, a low dielectric constant even with an increase in thickness.

Additional aspects will be set forth in part in the description which follows and, in part, will be apparent from the description, or may be learned by practice of various example embodiments.

According to various example embodiments, an amorphous boron nitride film includes an amorphous boron nitride compound doped with carbon atoms, wherein an sp² BN bonding structure and an sp³ BN bonding structure are included in the boron nitride film, wherein an sp²/sp³ conjugated —C═C—C═C— dopant structure is distributed in 60% or less of the entire amorphous film.

Alternatively or additionally according to some example embodiments, a semiconductor device includes a substrate and a wiring structure in or on the substrate, wherein the wiring structure includes a dielectric layer, a conductive wiring, and a diffusion barrier layer. The diffusion barrier layer includes an amorphous boron nitride film. The amorphous boron nitride film includes an amorphous boron nitride compound doped with carbon atoms, wherein an sp² BN bonding structure and an sp³ BN bonding structure are included in the boron nitride film, wherein an sp²/sp³ conjugated —C═C—C═C— dopant structure is distributed in 60% or less of the entire amorphous film.

Alternatively or additionally, a field effect transistor includes a source, a drain, a channel between the source and the drain, a gate facing the channel, a gate insulating layer between the gate and the channel, and spacers between the source and the gate and between the drain and the gate. The spacers includes an amorphous boron nitride film, wherein the amorphous boron nitride film includes an amorphous boron nitride compound doped with carbon atoms, and an sp² BN bonding structure and an sp³ BN bonding structure are included in the boron nitride film, wherein an sp²/sp³ conjugated —C═C—C═C— dopant structure is distributed in 60% or less of the entire amorphous film.

Alternatively or additionally according to some example embodiments, an image sensor includes a substrate, a plurality of photodiodes arranged on the substrate, and an amorphous boron nitride film on the plurality of photodiodes, wherein the amorphous boron nitride film includes an amorphous boron nitride compound doped with carbon atoms, and an sp² BN bonding structure and an sp³ BN bonding structure are included in the boron nitride film, wherein an sp²/sp³ conjugated —C═C—C═C— dopant structure is distributed in 60% or less of the entire amorphous film.

Alternatively or additionally, a method for manufacturing an amorphous boron nitride film includes preparing a substrate, and growing an amorphous boron nitride film on the substrate with plasma by using a first precursor containing nitrogen atoms and boron atoms and a second precursor containing carbon atoms at a temperature of about 23 ºC (room temperature) to about 500° C., wherein the amorphous boron nitride film includes an amorphous boron nitride compound doped with the carbon atoms, and an sp² BN bonding structure and an sp³ BN bonding structure are included in the boron nitride film, wherein an sp²/sp³ conjugated —C═C—C═C— dopant structure is distributed in 60% or less of the entire amorphous film.

### BRIEF DESCRIPTION OF THE DRAWINGS

The above and other aspects, features, and advantages of certain example embodiments of the disclosure will be more apparent from the following description taken in conjunction with the accompanying drawings, in which:

FIG. 1A is a set of scanning electron microscope (SEM) images showing changes in cross sections in the thickness direction according to increases in the thicknesses of carbon-undoped boron nitride films (Comparative Examples 2 and 4 to 6), and FIG. 1B is a set of SEM images showing changes in cross sections in the thickness direction according to increases in the thicknesses of carbon-doped boron nitride films (Examples 1 and 5 to 7);

FIG. 2 is a graph showing a change in dielectric constant according to increases in the thicknesses of a carbon-undoped boron nitride film and a carbon-doped boron nitride film;

FIG. 3 is a graph showing the FT-IR spectra of boron nitride films of Comparative Example 2 and Examples 1 to 4;

FIG. 4 is a schematic cross-sectional view illustrating the structure of an image sensor according to various example embodiments;

FIG. 5 is a schematic cross-sectional view illustrating the structure of a semiconductor device including a wiring structure, according to various example embodiments;

FIG. 6 is a schematic cross-sectional view illustrating the structure of a field effect transistor according to various example embodiments; and

FIG. 7 is a schematic cross-sectional view illustrating the structure of a field effect transistor according to various example embodiments.

### DETAILED DESCRIPTION

Reference will now be made in detail to various embodiments, examples of which are illustrated in the accompanying drawings, wherein like reference numerals refer to like elements throughout. In this regard, example embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

As examples described herein allows for various changes and numerous embodiments, particular example embodiments will be illustrated in the drawings and described in detail in the detailed description. However, this is not intended to limit inventive concepts to particular modes of practice, and it is to be understood that all changes, equivalents, and substitutes that fall within the technical scope of inventive concepts are encompassed herein.

Terms used herein are used only to describe specific example embodiments, but are not intended to limit inventive concepts. An expression in the singular includes an expression in the plural unless clearly otherwise from the context. Hereinafter, it is to be understood that terms such as “include” and “have” are used to indicate the presence of stated features, numbers, steps, operations, elements, parts, components, materials, or a combination thereof, but not to preclude the possibility of the presence or addition of one or more other features, numbers, steps, operations, elements, parts, components, materials, or combinations thereof.

In the drawings, the thicknesses of several layers and regions are exaggerated or reduced for clarity. Like reference numerals denote like elements throughout the specification. Throughout the specification, when an element, such as a layer, a film, a region, or a substrate, is referred to as being “on” or “above,” it may be directly on the other element or intervening elements may also be present. Throughout the specification, terms such as “first” or “second” may be used to describe various components, but components should not be limited by said terms. These terms are used only to distinguish one element from another element.

In addition, hereinafter, a device according to various example embodiments will be described in detail with reference to the accompanying drawings. In the drawings, like reference numerals denote like elements, and the size of each element in the drawings may be exaggerated for clarity and convenience of explanation. In addition, example embodiments described below are provided for illustrative purposes only, and these example embodiments allow for various changes.

Hereinafter, when referred to as being “above” or “on,” it may include not only the case of being directly on while being in contact, but also the case of being on while being not in contact. An expression in the singular includes an expression in the plural unless they are clearly different from each other in a context. In addition, when a part is referred to as “comprising” an element, it means that the part may further comprise other elements without precluding the other elements, unless otherwise specified.

The use of the term “the” and similar referents may be construed as covering both the singular and the plural. The steps of methods can be performed in any suitable order unless otherwise indicated herein or otherwise clearly contradicted, and are not necessarily limited to the order described herein.

In addition, terms such as “ . . . er or -or” and “module” as used herein refer to a unit that processes at least one function or operation and may be implemented as hardware, software or a combination thereof.

The connecting lines or connectors between elements illustrated in the drawings are intended to represent example functional relationship and/or physical or logical connections, and it should be noted that many alternative or additional functional relationships, physical connections, and/or logical connections may be present in a practical device.

The use of all examples or exemplary languages is intended merely to describe the technical ideas, and the scope is not construed as being limited by such examples or exemplary languages unless otherwise defined by claims.

An amorphous boron nitride film according to various example embodiments includes an amorphous boron nitride compound doped with carbon atoms, and an sp² BN bonding structure and an sp³ BN bonding structure are included in the boron nitride film, and an sp²/sp³ conjugated —C═C—C═C— dopant structure may be distributed in 60% or less of the entire amorphous film.

An existing boron nitride film may be manufactured through thin film growth by vapor deposition (such as chemical vapor deposition) of a compound consisting of boron and nitrogen atoms, such as borazine. However, as the thickness of such a boron nitride film increases, an energetically stable hexagonal crystalline phase (e.g., a h-BN structure) is generated by metastable internal film stress, and thus, there may be a limitation in the increase of the dielectric constant.

In contrast, since the amorphous boron nitride film according to various example embodiments includes an amorphous boron nitride film doped with carbon atoms, despite an increase in the thickness of the thin film, the sp²/sp³ conjugated —C═C—C═C— dopant structure intervenes or helps to intervene around the BN bond to alleviate internal film stress, and thus, crystallization is suppressed or more likely to be suppressed, and/or an amorphous phase can be maintained or more likely to be maintained. Therefore, even when the thickness of the amorphous boron nitride film according to various example embodiments increases, crystallization does not occur or is less likely to occur, and thus a low dielectric constant may be maintained or more likely to be maintained, and accordingly, the amorphous boron nitride film according to various example embodiments may be applied to various electronic devices.

In the amorphous boron nitride film according to various example embodiments, when the sp²/sp³ conjugated —C═C—C═C— dopant structure is distributed in 60% or less of the entire amorphous film, an increase in dielectric constant may be suppressed or at least partially suppressed. When the amount exceeds the above range, carbon atoms aggregate, thus exhibiting conductivity, which may result in an increased dielectric constant.

According to various example embodiments, the amorphous boron nitride film may have a dielectric constant of about 2.0 to about 4.0. For example, the amorphous boron nitride film may have a dielectric constant of about 2.0 to about 3.5, or about 2.0 to about 3.0.

According to various example embodiments, the amorphous boron nitride film may have a carbon content of 60 at % or less. For example, the carbon content of the amorphous boron nitride film may be 59 at % or less, 58 at % or less, 57 at % or less, 56 at % or less, 55 at % or less, 54 at % or less, 53 at % or less, 52 at % or less, 51 at % or less, 50 at % or less, 49 at % or less, 48 at % or less, 47 at % or less, 46 at % or less, 45 at % or less, 44 at % or less, 43 at % or less, 42 at % or less, 41 at % or less, 40 at % or less, 39 at % or less, 38 at % or less, 37 at % or less, 36 at % or less, 35 at % or less, 34 at % or less, 33 at % or less, 32 at % or less, 31 at % or less, 30 at % or less, 29 at % or less, 28 at % or less, 27 at % or less, 26 at % or less, 25 at % or less, 24 at % or less, 23 at % or less, 22 at % or less, 21 at % or less, 20 at % or less, 19 at % or less, 18 at % or less, 17 at % or less, 16 at % or less, or 15 at % or less. For example, the amorphous boron nitride film may have a carbon content of 1 at % or more, 2 at % or more, 3 at % or more, 4 at % or more, 5 at % or more, 6 at % or more, 7 at % or more, 8 at % or more, 9 at % or more, or 10 at % or more. The carbon content of the amorphous boron nitride film may have a combined range of the upper limit and the lower limit of the above-described carbon contents.

When the amorphous boron nitride film has a carbon content that satisfies the above-described carbon content range, the amorphous phase is maintained or more likely to be maintained, despite an increase in film thickness, and thus, an increase in the dielectric constant of the film may be suppressed or at least partially suppressed.

According to various example embodiments, a ratio (e.g. a B:N ratio) of B atoms to N atoms in the amorphous boron nitride film may be in a range of about 1.2:1 to about 2:1. For example, the ratio of B atoms to N atoms in the amorphous boron nitride film may be about 1.3:1 to about 1.9:1, about 1.3:1 to about 1.8:1, about 1.4:1 to about 1.7:1, or about 1.4:1 to about 1.6:1.

When the ratio (B:N ratio) of B atoms to N atoms in the amorphous boron nitride film satisfies the above range, a thin film having a low dielectric constant may be formed.

According to various example embodiments, the carbon atoms may be derived from methane, trimethylborazine, triethylborazine, tripropylborazine, tributylborazine, ethylene, acetylene, propylene, butylene, or a combination thereof. For example, the carbon atoms may be derived from methane, trimethylborazine, or a combination thereof.

According to various example embodiments, the amorphous boron nitride film may maintain an amorphous phase at a thickness of about 10 nm to about 20 nm. When a conventional carbon-undoped boron nitride film is grown to a thickness of greater than 10 nm, crystallization occurs. In contrast, even when the amorphous boron nitride film according to various example embodiments is grown by carbon doping to a thickness of greater than 10 nm, the formation of crystals is suppressed or is more likely to be suppressed, and thus the amorphous phase may be maintained or more likely to be suppressed.

According to various example embodiments, the amorphous boron nitride film may include carbon atoms, boron atoms, and nitrogen atoms, and the content of the boron atoms may be higher than the content of the nitrogen atoms.

According to various example embodiments, the amorphous boron nitride film may include carbon atoms, boron atoms, and nitrogen atoms, and a sum of the content of the boron and nitrogen atoms may be greater than the content of the carbon atoms.

Since the content of the boron atoms is greater than the content of the nitrogen atoms in the amorphous boron nitride film, an amorphous thin film may be induced. In addition, by adding carbon atoms as a doping amount, not only is the amorphous phase of the thin film maintained even when the thickness thereof increases, an increase in dielectric constant according to carbon aggregation can also be suppressed.

According to various example embodiments, the amorphous boron nitride film may have no absorption peak in a wavelength band of about 1400 cm⁻¹ to about 1600 cm⁻¹ of an FT-IR spectrum. The absorption peak in a wavelength band of about 1400 to about 1600 cm⁻¹ of an FT-IR spectrum indicates a crystalline B═N bond, and the amorphous boron nitride film according to various example embodiments does not have the corresponding absorption peak.

According to various example embodiments, the amorphous boron nitride film may have no phonon scattering signal in a wavelength band of about 1300 cm⁻¹ to about 1400 cm⁻¹ of a Raman spectrum. The absorption peak in a wavelength of about 1300 cm⁻¹ to about 1400 cm⁻¹ of a Raman spectrum is known as a phonon scattering signal of an sp² BN (hexagonal BN) structure, and the amorphous boron nitride film according to various example embodiments does not have the corresponding absorption peak, from which it can be seen that the amorphous boron nitride film does not include crystals or crystal grains.

A method of manufacturing an amorphous boron nitride film, according to various example embodiments, includes: preparing a substrate, and growing an amorphous boron nitride film on the substrate with plasma by using a first precursor containing nitrogen atoms and boron atoms and a second precursor containing carbon atoms at a temperature of about 23° ° C. to about 500° C., wherein the amorphous boron nitride film includes an amorphous boron nitride compound doped with the carbon atoms, and an sp² BN bonding structure and an sp³ BN bonding structure are included in the boron nitride film, and an sp²/sp³ conjugated —C═C—C═C— dopant structure is distributed in 60% or less of the entire amorphous film.

For example, the growth of the boron nitride film may be performed at about 23° C. (room temperature) to about 30° C., or about 23° C. to about 25° C.

According to various example embodiments, the substrate may also be a growth substrate for forming an amorphous boron nitride film. In this case, the substrate may include, for example, at least one of a semiconductor material, an insulating material, and a metal material. The semiconductor material may include a group IV semiconductor and/or a compound semiconductor. For example, the group IV semiconductor may include, but is not limited to, Si, Ge, or Sn. The compound semiconductor may include, for example, a semiconductor material obtained by combining at least two elements from Si, Ge, C, Zn, Cd, Al, Ga, In, B, C, N, P, S, Se, As, Sb, and Te, or a group III-V compound semiconductor. The insulating material may include, for example, at least one from an oxide, nitride or carbide of at least one of Si, Ni, Al, W, Ru, Co, Mn, Ti, Ta, Au, Hf, Zr, Zn, Y, Cr, Cu, Mo, and Gd, and a derivative thereof.

According to various example embodiments, the preparation of the substrate may include cleaning the substrate (e.g. with a wet clean), and treating a surface of the substrate with hydrogen (H₂) plasma at a temperature of about 100° C. to about 600° C.

The cleaning of the substrate may include immersing the substrate in an organic solvent such as acetone to perform ultrasound treatment, and then cleaning with nitrogen gas and/or an alcohol such as isopropyl alcohol. In some example embodiments, the substrate may be immersed in an acid solution such as hydrogen fluoride to remove a native oxide, and then the residual acid solution may be removed using anhydrous ethanol and nitrogen gas.

After the cleaning of the substrate, the surface of the substrate may be treated with H₂ plasma to remove or reduce impurities remaining on the surface, e.g., carbon impurities.

According to various example embodiments, the treatment of the surface of the substrate with H₂ plasma may include controlling a flow rate of H₂ to about 20 sccm to about 200 sccm and maintaining plasma power at about 20 W to about 100 W, or about 30 W to about 100 W.

According to various example embodiments, the growth of the amorphous boron nitride film on the substrate may include, while maintaining an Ar/H₂ mixed plasma, controlling a flow rate of a reaction gas of the first precursor to about 0.03 standard cubic centimeters (sccm) to about 1 sccm and controlling a flow rate of a reaction gas of the second precursor to about 0.03 sccm to about 1 sccm.

In the growth of the amorphous boron nitride film, a process pressure may be 10 mTorr or more. For example, the process pressure for growing the amorphous boron nitride film may be within a range of about 10 mTorr to about 1 Torr.

Subsequently, in a state in which the Ar/H₂ mixed plasma atmosphere is maintained, reaction gases for the growth of the amorphous boron nitride film are injected into a chamber. The reaction gases may include a first precursor and second precursor for the growth of the amorphous boron nitride film. The reaction gases may be pre-mixed and injected, or may be separately injected. In addition, the reaction gases may be injected simultaneously or sequentially.

The first precursor may be, for example, a source containing both nitrogen and boron, such as borazine (B₃N₃H₆) or ammonia-boran (NH₃—BH₃), and may be at least one thereof.

The second precursor may be, for example, a source containing carbon, such as methane, trimethylborazine, triethylborazine, tripropylborazine, tributylborazine, ethylene, acetylene, propylene, or butylene, and may include at least one thereof.

The reaction gases may further include a carrier gas. The carrier gas may include an inert gas. The inert gas may include, for example, at least one selected from argon gas, neon gas, nitrogen gas, helium gas, krypton gas, and xenon gas. In addition, the reaction gases may further include hydrogen gas, which may promote activation by plasma.

A mixing ratio of the reaction gases injected into the chamber may be adjusted by controlling the flow rates of the reaction gas of the first precursor, the reaction gas of the second precursor, an inert gas, and hydrogen gas that are introduced into the chamber. To form the amorphous boron nitride film, in the reaction gases, the content of the gas of the first precursor may be identical to or greater than the content of the gas of the second precursor. For example, the flow rate of the reaction gas of the first precursor may be controlled to about 0.03 sccm to about 1 sccm, and the flow rate of the reaction gas of the second precursor may be controlled to about 0.03 sccm to about 1 sccm.

According to various example embodiments, the reaction gas of the second precursor may be controlled such that a content of carbon in the amorphous boron nitride film is 60 at % or less.

According to various example embodiments, the first precursor may include a borazine compound, and the second precursor may include methane, trimethylborazine, triethylborazine, tripropylborazine, tributylborazine, ethylene, acetylene, propylene, butylene, or a combination thereof.

While the reaction gases are introduced into the chamber, the plasma power may be maintained within a range of about 10 W to about 30 W, or about 10 W to about 20 W, and the process temperature may be maintained within a range of about 23° ° C. to about 500° C. A plasma device may be or include or be included in, but is not limited to, a device for providing plasma including one or more of inductively coupled plasma, microwave plasma, capacitively coupled discharge plasma, electron cyclotron resonance plasma, or helicon plasma. When an electric field is induced inside a chamber of the plasma device, plasma for the growth of the amorphous boron nitride film may be generated by the induced electric field.

According to various example embodiments, the amorphous boron nitride film may be grown on the substrate by plasma chemical vapor deposition (CVD), or plasma enhanced CVD (PECVD) of the reaction gas of the first precursor and the reaction gas of the second precursor.

For example, nitrogen, boron and carbon atoms are activated by plasma of a reaction gas in which the reaction gas of the first precursor containing nitrogen and boron atoms, the reaction gas of the second precursor containing carbon, a carrier gas, and hydrogen gas are mixed, and the activated nitrogen atoms (N*), boron atoms (B*) and carbon atoms (C*) may be adsorbed onto the surface of the substrate. In addition, plasma of the carrier gas continues to induce the activation of the substrate, thus enabling acceleration of the adsorption of the activated nitrogen atoms (N*), the activated boron atoms (B*), and the activated carbon atoms (C*) on the surface of the substrate.

Accordingly, a carbon-doped amorphous boron nitride film may be grown on the surface of the substrate, and an sp² BN bonding structure and an sp³ BN bonding structure are included in the boron nitride film, and an sp²/sp³ conjugated —C═C—C═C— dopant structure may be included in an amount of 60% or less in the entire amorphous film.

The amorphous boron nitride film formed on the substrate may be separated from the substrate and transferred to another substrate or device. In various example embodiments, the amorphous boron nitride film may also be grown, e.g. directly grown on an intermediate structure for manufacturing various electronic devices such as one or more of image sensors, display devices, field effect transistors, solar cells, and display devices.

As described above, the amorphous boron nitride film according to various example embodiments has a low dielectric constant, and thus may be applied to various electronic devices. For example, the amorphous boron nitride film according to various example embodiments may be used as one or more of an interlayer insulating film, a spacer, or a device isolation layer in the integrated circuits of various electronic devices, including one or more of an image sensor, a field effect transistor, a memory device, a display device, and the like.

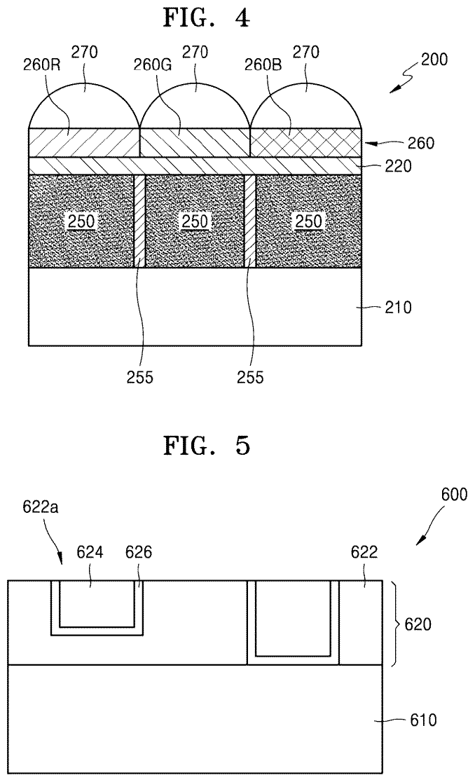

FIG. 4 is a schematic cross-sectional view illustrating the structure of an image sensor 200 according to various example embodiments. Referring to FIG. 4, the image sensor 200 may include a substrate 210, a plurality of photodiodes 250 arranged on the substrate 210, an amorphous boron nitride film 220 arranged on the plurality of photodiodes 250, and a color filter layer 260 arranged on the amorphous boron nitride film 220.

The plurality of photodiodes 250 may be arranged in, e.g. within, the substrate 210 in the form of a two-dimensional array. A black matrix 255 may be arranged between adjacent two photodiodes 250. The photodiodes 250 serve to convert incident light into electrical energy, and a metal wiring (not shown) for detecting the electrical energy generated from the photodiodes 250 may be arranged in the substrate 210.

The color filter layer 260 may include a plurality of color filters 260R, 260G, and 260B arranged to correspond to the plurality of photodiodes 250. The plurality of color filters 260R, 260G, and 260B may include, for example, a red color filter 260R, a green color filter 260G, and a blue color filter 260B. However, the color filters are not limited to the above examples, and may or may not be arranged as a Bayer pattern. The color filter layer 260 may further include a plurality of microlenses 270 arranged to correspond to the plurality of color filters 260R, 260G, and 260B.

The amorphous boron nitride film 220 may be arranged between the color filter layer 260 and the photodiodes 250. In this regard, the amorphous boron nitride film 220 serves to prevent or reduce the reflection of light incident through the color filter layer 260, and may have a low refractive index and high hardness. The amorphous boron nitride film 220 has already been described, and thus, a description thereof will not be provided herein. The amorphous boron nitride film 220 may be applied to the image sensor 200 as an anti-reflection film, and thus, the light concentration of each of a plurality of pixels may be improved, and light interference that may occur between pixels may be prevented or reduced.

FIG. 5 is a schematic cross-sectional view illustrating the structure of a semiconductor device 600 including a wiring structure, according to various example embodiments. Referring to FIG. 5, the semiconductor device 600 may include a substrate 610 and a wiring structure 620 arranged on the substrate 610. The wiring structure 620 may include a dielectric layer 622, a conductive wiring 624, and a diffusion barrier layer 626.

The substrate 610 may be or include or be included in a semiconductor substrate. For example, the substrate 610 may include a group IV semiconductor material, a group III-V compound semiconductor material, or a group II-VI compound semiconductor material. For example, the substrate 610 may include at least one semiconductor material selected from Si, Ge, SiC, SiGe, SiGeC, Ge Alloy, GaAs, InAs, and InP. This is only an example, and various other semiconductor materials may also be used as a substrate. In addition, the substrate 610 may include a single layer or a plurality of layers in which different materials are stacked. For example, the substrate 610 may include a silicon-on-insulator (SOI) substrate and/or a silicon germanium-on-insulator (SGOI) substrate. In addition, the substrate 610 may include at least one semiconductor element (not shown). The semiconductor device may include, for example, at least one of a transistor, a capacitor, a diode, a memristor, and a resistor.

The dielectric layer 622 is disposed on the substrate 610. The dielectric layer 622 may have a single layer structure or a multilayer structure in which different dielectric materials are laminated. The dielectric layer 622 may include a dielectric material used in a general semiconductor manufacturing process. For example, the dielectric layer 622 may include one or more of silicon oxide, silicon nitride, silicate, or the like. However, this is only an example, and various other electric materials may be used as the dielectric layer 622. In addition, the dielectric layer 622 may also include an SiCOH-based organic-inorganic hybrid dielectric material. In addition, the dielectric layer 622 may also include an amorphous boron nitride film according to various example embodiments. When the dielectric layer 622 includes an amorphous boron nitride film, the dielectric layer 622 may also function as the diffusion barrier layer 626. In this case, the diffusion barrier layer 626, which will be described below, may also be omitted.

At least one trench 622a may be formed in the dielectric layer 622 to a predetermined depth. In this regard, the at least one trench 622a may be formed not to contact the substrate 610 or may be formed to contact the substrate 610. FIG. 5 illustrates a case in which two trenches 622a are formed in the dielectric layer 622, one of the two trenches 622a is formed not to contact the substrate 610, and the other thereof is formed to contact the substrate 610.

The conductive wiring 624 is provided to fill the inside of the trench 622a. The conductive wiring 624 may include a highly conductive metal or metal alloy. For example, the conductive wiring 624 may include one or more of Cu, Ru, Al, Co, W, Mo, Ti, Ta, Ni, Pt, Cr, Rh, Ir, or an alloy thereof. However, the conductive wiring 624 is not limited to the above example, and various other metals may be used as the conductive wiring 624.

The diffusion barrier layer 626 is arranged on inner walls of the trench 622a. In this regard, the diffusion barrier layer 626 may be arranged to cover the conductive wiring 624 between the dielectric layer 622 and the conductive wiring 624. For example, the diffusion barrier layer 626 may be arranged on the inner walls of the trench 622a to cover side surfaces and lower surface of the conductive wiring 624. An upper surface of the conductive wiring 624 may be exposed by the diffusion barrier layer 626. The diffusion barrier layer 626 may serve to prevent or reduce the diffusion of a material constituting the conductive wiring 624. Meanwhile, the diffusion barrier layer 626 may further act as an adhesive layer between the dielectric layer 622 and the conductive wiring 624. The diffusion barrier layer 626 may include an amorphous boron nitride film according to embodiments.

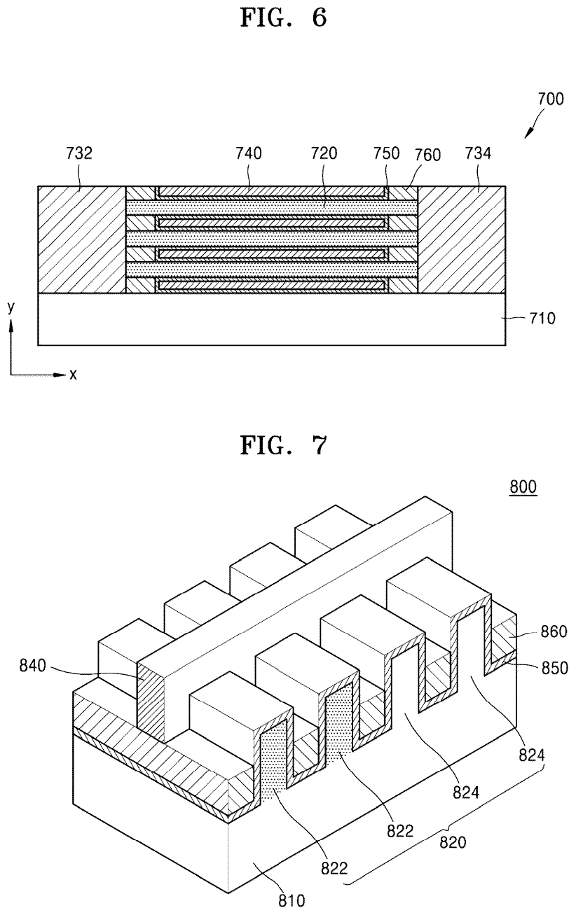

FIG. 6 is a schematic cross-sectional view illustrating the structure of a field effect transistor 700 according to various example embodiments. Referring to FIG. 6, the field effect transistor 700 may include a substrate 710, a plurality of channels 720 provided on the substrate 710, a source 732 and a drain 734 that contact the channels 720, and a plurality of gates 740 spaced apart from the plurality of channels 720. The source 732 and the drain 734 are spaced apart from each other in a first direction (e.g., an X direction), and the plurality of channels 720 may be spaced apart from each other between the source 732 and the drain 734 in a second direction (e.g., a Y direction).

The plurality of gates 740 are spaced apart from each channel 720 and face each other, and a gate insulating layer 750 may be provided between each gate 740 and each channel 720. For example, the gate insulating layer 750 may be arranged to cover at least a portion of the gate 740. For example, the gates 740 and the channels 720 may be alternately arranged in the second direction, and the gate insulating layer 750 may have a form surrounding the gate 740. The gate insulating layer 750 insulates the channel 720 from the gate 740 and may inhibit or reduce leakage current.

A contact between each channel 720 and the source 732 and a contact between each channel 720 and the drain 734 may have an edge contact form. For example, both ends of the channel 720 may contact the source 732 and the drain 734, respectively.

Each gate 740 is spaced apart from the source 732 and the drain 734, and spacers 760 may further be provided between the gate 740 and the source 732 and between the gate 740 and the drain 734. Since the source 732, the gates 740, and the drain 734 are arranged in the first direction, parasitic capacitance may occur between the source 732 and each gate 740 and between each gate 740 and the drain 734.

To reduce the parasitic capacitance, the spacers 760 may include an amorphous boron nitride film according to various example embodiments. The amorphous boron nitride film according to some example embodiments has a relatively low dielectric constant of about 2.0 to about 4.0 at an operating frequency of 100 kHz, and thus, parasitic capacitance may be effectively reduced. Alternatively or additionally, the amorphous boron nitride film according to some example embodiments has improved or excellent mechanical characteristics, and thus, the spacers 760 may support the channels 720 provided thereon.

The field effect transistor 700 may have a multi-bridge form in which both ends of each of the plurality of channels 720 contact the source 732 and the drain 734 and the plurality of channels 720 are spaced apart from each other and stacked in a direction away from the substrate 710. In some example embodiments, the field effect transistor 700 may be or may include or be included in a multi-bridge channel FET (MBCFETT); however, example embodiments are not limited thereto. Channels having such a multi-bridge form can reduce a short channel effect and reduce an area occupied by a source/a drain, and thus may be suitable for high integration. In addition, a uniform source/drain junction capacitance may be maintained regardless of the location of channels, and thus, the field effect transistor 700 may be applied to a high-speed and high-reliability device.

The gate insulating layer 750 may include a dielectric material having a relatively high dielectric constant. The gate insulating layer 750 may include, for example, aluminum oxide, hafnium oxide, zirconium oxide, and lanthanum oxide. However, the dielectric material is not limited to the above example. In various example embodiments, the gate insulating layer 750 may include a ferroelectric material. When the gate insulating layer 750 includes a ferroelectric material, the field effect transistor 700 may be applied to, for example, a logic device or a memory device. In various example embodiments, the gate insulating layer 750 may have a multilayer structure including a material with a high dielectric constant and a ferroelectric material.

FIG. 7 is a schematic cross-sectional view illustrating the structure of a field effect transistor 800 according to various example embodiments. Referring to FIG. 7, the field effect transistor 800 is an FinFET having a fin structure protruding on a substrate 810. The field effect transistor 800 may use protruding fin structures 822 and 824 as a channel 820, and thus may sufficiently secure a channel length. Accordingly, the short channel effect may be prevented or minimized, or reduced, and the occurrence of leakage current and area problems may be reduced.

The field effect transistor 800 may include the substrate 810, active fins 822, dummy fins 824, a gate 840, a gate insulating layer 850, and spacers 860. Although not shown in the drawing, both ends of each of the active fins 822 are electrically connected to a source and a drain. Although two active fins 822 are illustrated as a channel, the number of the active fins 822 is not limited thereto. The active fins 822 and the dummy fins 824 may be connected to the substrate 810. In various example embodiments, the active fins 822 may be active regions in which vertically protruding portions are doped with n+ or p+ impurities, and the dummy fins 824 may be regions in which vertically protruding portions are not doped. In some example embodiments, both the active fins 822 and the dummy fins 824 may also be n+- or p+-doped active regions. Each of the active fins 822 may have a width and a height, and the widths and heights of the active fins 822 may determine the width and height of the channel 820. The width and height of the channel 820 may be increased by the number of the active fins 822.

The gate insulating layer 850 may be provided on the active fins 822 and the dummy fins 824. The gate insulating layer 850 may include any one of an oxide layer, a nitride layer, or an oxynitride layer.

The spacers 860 may be provided in spaces between the active fins 822 and the dummy fins 824 to have a certain thickness. The spacers 860 may include an amorphous boron nitride film according to embodiments. Since the spacers 860 are provided between the active fins 822 and the dummy fins 824, the spacers 860 may be used as device isolation layers and reduce parasitic capacitance.

The gate 840 may be provided on the gate insulating layer 850 and the spacers 860. The gate 840 may have a structure covering the active fins 822, the dummy fins 824, and the spacers 860. In other words, the active fins 822 and the dummy fins 824 may have a structure provided inside the gate 840.

The semiconductor device, the field effect transistor, and the image sensor have been described with reference to embodiments illustrated in the drawings. However, these are provided for illustrative purposes only and it will be understood by those of ordinary skill in the art that various changes and other example embodiments equivalent thereto can be made therefrom.

Hereinafter, inventive concepts will be described in more detail with reference to the following examples and comparative examples. However, these examples are provided for illustrative purposes only and are not intended to limit the scope of the present inventive concept.

### EXAMPLES

### [Example 1] (Carbon Source—0.05 Sccm CH₄, Thin Film Thickness—16.2 nm)

Borazine and CH₄ gas were added at flow rates of 0.1 sccm and 0.05 sccm onto a silicon substrate at room temperature (23° C.) and a pressure of 120 mTorr in a 10 sccm hydrogen atmosphere, and a reaction was allowed to occur therebetween with 10 W plasma for 30 minutes, thereby manufacturing an amorphous boron nitride film having a thickness of 16.2 nm and doped with 21.9 wt % of carbon.

### [Example 2] (Carbon Source—TMB (0.3 Sccm), Thin Film Thickness—28.4 nm)

Borazine and TMB were added at flow rates of 0.1 sccm and 0.3 sccm onto a silicon substrate at room temperature (23° C.) and a pressure of 120 mTorr in a 10 sccm hydrogen atmosphere, and a reaction was allowed to occur therebetween with 20 W plasma for 60 minutes, thereby manufacturing an amorphous boron nitride film having a thickness of 28.4 nm and doped with 14.5 wt % of carbon.

### [Example 3] (Carbon Source—TMB (0.5 Sccm), Thin Film Thickness—32.9 nm)

A carbon-doped amorphous boron nitride film was obtained in the same manner as in Example 2, except that the flow rate of trimethylborazine was controlled to 0.5 sccm. A reaction was allowed to occur therebetween for 60 minutes, thereby manufacturing an amorphous boron nitride film having a thickness of 32.9 nm and doped with 16.2 wt % of carbon.

### [Example 4] (Carbon Source—TMB (1 Sccm), Thin Film Thickness—51.9 nm)

A carbon-doped amorphous boron nitride film was obtained in the same manner as in Example 2, except that the flow rate of trimethylborazine was controlled to 1 sccm. A reaction was allowed to occur therebetween for 60 minutes, thereby manufacturing an amorphous boron nitride film having a thickness of 51.9 nm and doped with 23.1 wt % of carbon.

### [Example 5] (Carbon Source—CH₄, Thin Film Thickness—3.7 nm)

A carbon-doped amorphous boron nitride film grown to a thickness of 3.7 nm was obtained in the same manner as in Example 1, except that the deposition time of a methane gas was changed to 5 minutes.

### [Example 6] (Carbon Source—CH₄, Thin Film Thickness—4.7 nm)

A carbon-doped amorphous boron nitride film grown to a thickness of 4.7 nm was obtained in the same manner as in Example 1, except that the deposition time of a methane gas was changed to 10 minutes.

### [Example 7] (Carbon Source—CH₄, Thin Film Thickness—10.1 nm)

A carbon-doped amorphous boron nitride film grown to a thickness of 10.1 nm was obtained in the same manner as in Example 1, except that the deposition time of a methane gas was changed to 20 minutes.

### [Comparative Example 1] (Reaction Gas—Borazine, Thin Film Thickness—17.3 nm)

Borazine was added at a flow rate of 0.1 sccm onto a silicon substrate at 400° C. and a pressure of 120 mTorr in a 10 sccm hydrogen atmosphere, and a reaction was allowed to occur therebetween with 30 W plasma for 90 minutes, thereby manufacturing an amorphous boron nitride film having a thickness of 17.3 nm and doped with 9.9 w % of carbon.

### [Comparative Example 2] (Reaction Gas—Borazine, Thin Film Thickness—3.9 nm)

A boron nitride film was obtained in the same manner as in Comparative Example 1, except that the plasma power was changed to 10 W, and the deposition time was 60 minutes.

### [Comparative Example 3] (Reaction Gas—TMB, Thin Film Thickness—16.2 nm)

TMB was added at a flow rate of 2 sccm onto a silicon substrate at room temperature (23° C.) and a pressure of 120 mTorr in a 10 sccm hydrogen atmosphere, and a reaction was allowed to occur therebetween with 10 W plasma for 90 minutes, thereby manufacturing an amorphous boron nitride film having a thickness of 16.2 nm and doped with 14.1 w % of carbon.

### [Comparative Example 4] (Reaction Gas—Borazine, Thin Film Thickness—7.1 nm)

A boron nitride film was obtained in the same manner as in Comparative Example 1, except that the plasma power was changed to 10 W, and the deposition time was 90 minutes.

### [Comparative Example 5] (Reaction Gas—Borazine, Thin Film Thickness—11.5 nm)

A boron nitride film was obtained in the same manner as in Comparative Example 1, except that the plasma power was changed to 10 W, and the deposition time was 120 minutes.

### [Comparative Example 6] (Reaction Gas—Borazine, Thin Film Thickness—16.7 nm)

A boron nitride film was obtained in the same manner as in Comparative Example 1, except that the plasma power was changed to 10 W, and the deposition time was 270 minutes.

### Evaluation Example 1: Evaluation of Cross-Sectional Appearance of Boron Nitride Film According to Thin Film Thickness

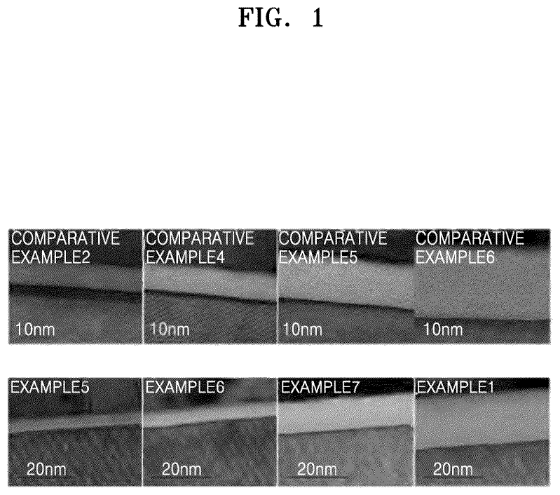

The boron nitride films obtained in Examples 1 and 5-7 and the boron nitride films obtained in Comparative Examples 2 and 4-6 were cut in the thickness direction, and cross-sections thereof were observed using an SEM and are illustrated in FIG. 1.

Referring to FIG. 1, it may be seen that, even when the thicknesses of the carbon-doped boron nitride films (Examples 1 and 5-7) increase, the amorphous phase is well maintained, whereas it can be confirmed that, when the thicknesses of the carbon-undoped boron nitride films (Comparative Examples 2 and 4-6) exceed 10 nm, a hexagonal BN crystalline structure (h-BN) appears.

### Evaluation Example 2: Evaluation of Dielectric Constant of Boron Nitride Film According to Thin Film Thickness

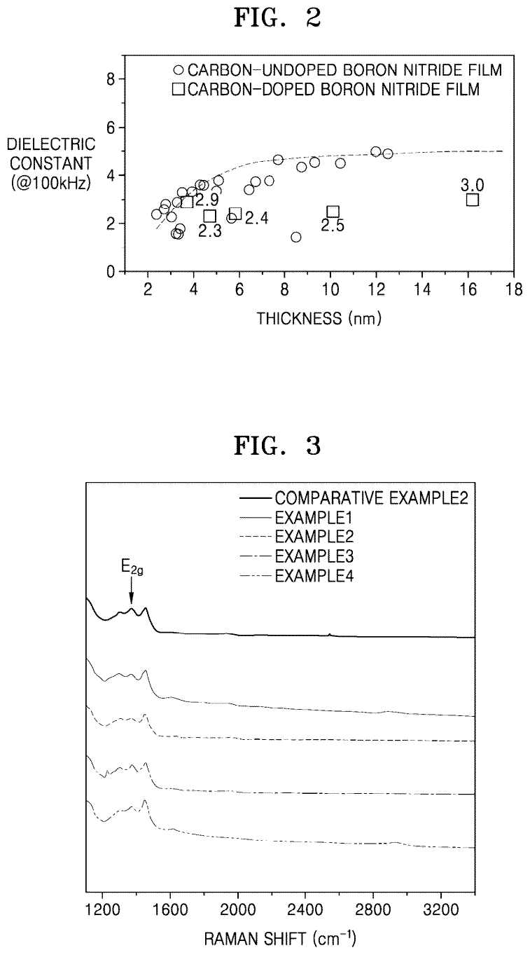

The dielectric constants of the boron nitride films obtained in Examples 5-8, having the respective thicknesses, and boron nitride films obtained in the same manner as in Comparative Example 2 while increasing the deposition time and thickness were measured using an electrical capacitor element measurement method, and the results thereof are illustrated in FIG. 2.

Referring to the square dots of FIG. 2, it can be confirmed that, even when the thickness of each of the carbon-doped boron nitride films (Examples 5-8) increases, the dielectric constant did not increase greatly. In contrast, referring to circular dots of FIG. 2, it can be confirmed that, as the thickness of the carbon-undoped boron nitride film increases from 2 nm, the dielectric constant increases, and the case of a thickness of greater than 8 nm, the dielectric constant reaches to 5.

### Evaluation Example 3: FT-IR Analysis

Spectra of the boron nitride films of Comparative Example 2 and Examples 1 to 4 were obtained using an FT-IR analyzer, and the results thereof are illustrated in FIG. 3.

Referring to FIG. 3, it can be confirmed that the carbon-doped boron nitride films (Examples 1 to 4) have no absorption peak in a wavelength band of 1400 cm⁻¹ to 1600 cm⁻¹, and have no phonon scattering signal in a wavelength band of 1300 cm⁻¹ to 1400 cm⁻¹.

### Evaluation Example 4: Atomic Ratio in Boron Nitride Film

An atomic ratio in each of the boron nitride films of Comparative Example 2 and Examples 1 to 4 was analyzed using an XPS analysis method, and the results thereof are shown in Table 1 below.

TABLE 1

| | Boron (at %) | Nitrogen (at %) | Carbon (at %) |
|---|---|---|---|
| Comparative | 42.1 | 39.4 | 8.8 |
| Example 2 | | | |
| Example 1 | 45.5 | 31.9 | 22.6 |
| Example 2 | 50.5 | 35.0 | 14.5 |
| Example 3 | 48.7 | 35.0 | 16.2 |
| Example 4 | 44.6 | 32.2 | 23.1 |

### Evaluation Example 5: Evaluation of Physical Characteristics of Boron Nitride Film

The dielectric constant, B/N ratio, and C content (at %) of each of the boron nitride films obtained in Comparative Examples 1 to 3 and Examples 1 to 4 were measured, and the results thereof are shown in Table 2 below.

### <Measurement Method>

Dielectric constant: A grown thin film and an upper electrode were deposited on a highly-doped N-type Si (metallic) substrate by using a shadow mask and a metal evaporator process, respectively. After measurement by a capacitance-voltage sweep using a metal-insulator-metal (MIM) simulated structure, the dielectric constant was extracted on the basis of the thickness of the dielectric film and the area of the upper electrode.

B/N ratio: The component ratio was extracted by an X-ray photoelectron spectroscopy (XPS) method using an area ratio of the spectra of boron 1s and nitrogen 1s signals and a sensitivity factor for each binding element.

C content: The content was calculated by dividing the area of a carbon 1s component spectrum by the total component area by using the same XPS measurement method as that used above with regard to the B/N component ratio.

Thickness: For ellipsometry measurement, the thickness was first measured by an optical analysis method immediately after deposition, and the thickness was corrected by transmission electron microscopy (TEM) after cross-section sampling.

TABLE 2

| | Di- | | C | Thick- | |
|---|---|---|---|---|---|
| | electric | B/N | content | ness | |
| | constant | ratio | (at %) | (nm) | Crystal |
| Comparative | 4.2 | 1.35:1 | 9.9 | 17.3 | Nano- |
| Example 1 | | | | | crystals |
| Comparative | 1.9 | 1.06:1 | 8.8 | 3.9 | Amorphous |
| Example 2 | | | | | |
| Comparative | 2.9 | 1.17:1 | 14.1 | 16.2 | Amorphous |
| Example 3 | | | | | |
| Example 1 | 2.8 | 1.42:1 | 21.9 | 16.2 | Amorphous |
| Example 2 | 3.0 | 1.44:1 | 14.5 | 28.4 | Amorphous |
| Example 3 | 3.3 | 1.39:1 | 16.2 | 32.9 | Amorphous |
| Example 4 | 3.7 | 1.38:1 | 23.1 | 51.9 | Amorphous |

As shown in Table 2 above, even when the thickness of a carbon-doped amorphous boron nitride film according to various example embodiments of the disclosure increases, crystallization is suppressed by carbon doping, and thus, the amorphous phase is maintained, and accordingly, the film may have a low dielectric constant.

As is apparent from the foregoing description, an amorphous boron nitride film according to various example embodiments includes a carbon-doped amorphous boron nitride compound, and an sp² BN bonding structure and an sp³ BN bonding structure are included in the boron nitride film, and an sp²/sp³ conjugated —C═C—C═C— dopant structure is distributed in 60% or less of the entire amorphous film. Thus, in a process of growing the boron nitride film in the thickness direction, no hexagonal-boron nitride (h-BN) crystal is formed and the amorphous phase is maintained or significantly or at least partially maintained, and accordingly, an increase in dielectric constant is suppressed or significantly or at least partially suppressed.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., +10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%)

It should be understood that various example embodiments described herein should be considered in a descriptive sense only and not for purposes of limitation. Descriptions of features or aspects within each example embodiment should typically be considered as available for other similar features or aspects in other example embodiments, and example embodiments are not necessarily mutually exclusive with one another. While one or more example embodiments have been described with reference to the figures, it will be understood by those of ordinary skill in the art that various changes in form and details may be made therein without departing from the spirit and scope as defined by the following claims.

1. An amorphous boron nitride film comprising
an amorphous boron nitride (BN) compound doped with carbon atoms, wherein
an sp² BN bonding structure and an sp³ BN bonding structure are included in the boron nitride film, and
an sp²/sp³ conjugated —C═C—C═C— dopant structure is distributed in 60% or less of the entire amorphous film.

2. The amorphous boron nitride film of claim 1, wherein the amorphous boron nitride film has a dielectric constant of about 2.0 to about 4.0.

3. The amorphous boron nitride film of claim 1, wherein the amorphous boron nitride film has a carbon content of 60 at % or less.

4. The amorphous boron nitride film of claim 1, wherein a B:Nratio of B atoms to N atoms in the amorphous boron nitride film is in a range of about 1.2:1 to about 2:1.

5. The amorphous boron nitride film of claim 1, wherein the carbon atoms are methane carbon atoms, trimethylborazine carbon atoms, triethylborazine carbon atoms, tripropylborazine carbon atoms, tributylborazine carbon atoms, ethylene carbon atoms, acetylene carbon atoms, propylene carbon atoms, butylene carbon atoms, or a combination thereof.

6. The amorphous boron nitride film of claim 1, wherein the amorphous boron nitride film maintains an amorphous phase at a thickness of about 10 nm to about 20 nm.

7. The amorphous boron nitride film of claim 1, wherein
the amorphous boron nitride film comprises carbon atoms, boron atoms, and nitrogen atoms, and
a content of the boron atoms is higher than a content of the nitrogen atoms.

8. The amorphous boron nitride film of claim 1, wherein the amorphous boron nitride film has no absorption peak in a wavelength band of about 1400 cm⁻¹ to about 1600 cm⁻¹ of a Fourier transform infrared spectroscopy (FT-IR) spectrum.

9. The amorphous boron nitride film of claim 1, wherein the amorphous boron nitride film has no phonon scattering signal in a wavelength band of about 1300 cm⁻¹ to about 1400 cm⁻¹ of a Raman spectrum.

10. A semiconductor device comprising:
a substrate; and
a wiring structure on the substrate, wherein
the wiring structure includes a dielectric layer, a conductive wiring, and a diffusion barrier layer,
the diffusion barrier layer includes an amorphous boron nitride film,
the amorphous boron nitride film includes an amorphous boron nitride compound doped with carbon atoms, and
an sp² BN bonding structure and an sp³ BN bonding structure are included in the boron nitride film, wherein an sp²/sp³ conjugated —C═C—C═C— dopant structure is distributed in 60% or less of the entire amorphous film.

11. The semiconductor device of claim 10, wherein the diffusion barrier layer is interposed between the dielectric layer and the conductive wiring.

12.-13. (canceled)

14. A method of manufacturing an amorphous boron nitride film, the method comprising:
preparing a substrate; and
growing an amorphous boron nitride film on a substrate with plasma by using a first precursor containing nitrogen atoms and boron atoms and a second precursor containing carbon atoms, at a temperature of about 23° C. (room temperature) to about 500° C.,
wherein the amorphous boron nitride film includes an amorphous boron nitride compound doped with carbon atoms, and
an sp² BN bonding structure and an sp³ BN bonding structure are included in the boron nitride film, wherein an sp²/sp³ conjugated —C═C—C═C— dopant structure is distributed in 60% or less of the entire amorphous film.

15. The method of claim 14, wherein the preparation of the substrate comprises:
cleaning the substrate; and
treating a surface of the substrate with hydrogen plasma at a temperature of about 100° C. to about 600° C.

16. The method of claim 15, wherein the treatment of the surface of the substrate with hydrogen plasma comprises controlling a flow rate of H₂ to about 20 standard cubic centimeters (sccm) to about 200 sccm and maintaining plasma power at about 20 W to about 100 W.

17. The method of claim 14, wherein the growth of the amorphous boron nitride film on the substrate comprises, while maintaining an Ar/H₂ mixed plasma, controlling a flow rate of a reaction gas of the first precursor to about 0.03 sccm to about 1 sccm and controlling a flow rate of a reaction gas of the second precursor to about 0.03 sccm to about 1 sccm.

18. The method of claim 17, wherein the reaction gas of the second precursor is controlled such that a content of carbon in the amorphous boron nitride film is 60 at % or less.

19. The method of claim 14, wherein
the first precursor comprises a borazine compound, and
the second precursor comprises methane, trimethylborazine, triethylborazine, tripropylborazine, tributylborazine, ethylene, acetylene, propylene, butylene, or a combination thereof.

20. The method of claim 14, wherein the amorphous boron nitride film is grown on the substrate by plasma chemical vapor deposition (CVD).
